(19) United States
(12) Patent Application Publication
(10) Pub. No.: US 2025/0390151 A1
(43) Pub. Date: Dec. 25, 2025

(54) TEMPERATURE SENSING UNIT AND TEMPERATURE SENSING METHOD FOR AI LAPTOP

(71) Applicant: ORIENTAL SYSTEM TECHNOLOGY INC., Hsin-Chu (TW)

(72) Inventors: Chun-Chiang CHEN, Zhubei City (TW); Chein-Hsun WANG, Hsin-Chu (TW); Jen-Ping KU, Hsinchu County (TW)

(21) Appl. No.: 18/799,993

(22) Filed: Aug. 9, 2024

(30) Foreign Application Priority Data
Jun. 21, 2024 (TW) 113123165

(51) Int. Cl. G06F 1/20; G01J 5/12; G01K 7/22; H05K 7/20

(52) U.S. Cl. CPC G06F 1/203; G01J 5/12; G01K 7/22; H05K 7/20209

(57) ABSTRACT

A temperature sensing unit for AI laptop is proposed that can measure inside temperature of in-machine (Ta), Target area temperature (Tb) and provide calculated ambient temperature (Tamb) for Fan speed and ON/OFF control to offer sustained optimized AI computing power and maintain better user experience. One implementation of the invention is to use dual thermopile sensors for thermal-shock resistance and high accuracy in temperature measurement with one thermopile sensor as active element to sense temperature of target area and another one thermopile sensor as dummy element for encapsulation effect compensation to improve accuracy of temperature reading. One embodiment of the invention is to estimate the skin temperature of laptop which is away from the location of thermopile sensor.

### BACKGROUND OF THE DISCLOSURE

### Technical Field

The present disclosure relates to a temperature sensor, particularly relates to a temperature sensing unit and a temperature sensing method for an artificial intelligence (AI) laptop.

### Description of Related Art

Apart from the central processing unit (CPU) and the graphics processing unit (GPU), AI laptop further has a neural processing unit (NPU). The overall computing capability needs to be at least 45 TOPS (tera operations per second) or higher to process real-time voice and video signal. With the rapid increased larger inference model during AI training, the need of computing power is greatly increased, and the power consumption is relatively increased by 2-3 times as well, for example, 80-130 Watt for AI laptop. Therefore, the heat management for laptop is becoming important to prevent the chips from overheating and downclocking, which may significantly downgrade the computing power and impact user experience.

The implementation of heat management for laptop is different from that of desktop computer or AI server. Conventional heat management for desktop computer and AI server are water-cooling manner or the mixed manner of water cooling and air cooling. AI lap top can only use fan cooling for heat management due to the height and weight constraints of AI laptop. Traditional gaming laptop adopted the manners of increasing the volume of metal casing and/or continually activating the fan has problem of fan noise which greatly impacts the user experience.

Alternative approach is using the build-in temperature sensor of CPU chip or a thermistor attached to the casing to control the activation and/or speed of the fan. However, those may be close to the heat source, and the severe temperature change may generate annoying fan switching noise. More importantly, AI generation output might have severe delay due to computing power is affected by the over-hated chip. Therefore, a complete solution is needed for applying to AI laptop to provide optimized sustained computing power and to decrease fan noise.

### SUMMARY OF THE INVENTION

The disclosure adopts non-contact temperature sensor incorporated with calibration and algorithm to provide completely integrated AI laptop heat management to output optimized sustained computing power and decrease fan noise. Furthermore, the disclosure may effectively adjust the apparent temperature at keyboard for better user experience, which is integrated into the heat management system of AI laptop.

One embodiment of the disclosure provides a temperature sensing unit used for an AI laptop, the temperature sensing unit including: a non-contact temperature sensor, sensing an in-machine temperature (Ta) and a target area temperature (Tb); and a processing element, obtaining a ratio of a first thermal resistance (Rac), which is between the target area temperature and an external ambient temperature, and a second thermal resistance (Ri), which is between the in-machine temperature and the target area temperature through a calibration procedure, calculating a predicting external ambient temperature (Tamb) according to, Tamb=Tb−(Ta−Tb)×(Rac/Ri), according to the in-machine temperature, the target area temperature, and the predicting external ambient temperature, to control the activation and speed of a fan, and/or to optimize sustained computing power for AI laptop.

Another embodiment of the disclosure provides a temperature sensing unit used for an AI laptop, the temperature sensing unit including: a non-contact temperature sensor, sensing an in-machine temperature (Ta) and a target area temperature (Tb); and a processing element, obtaining a first ratio of a first thermal resistance (Rac), which is between the target area temperature and an external ambient temperature, and a second thermal resistance (Ri), which is between the in-machine temperature and the target area temperature through a first calibration procedure, calculating a predicting external ambient temperature (Tamb) according to, Tamb=Tb−(Ta−Tb)×(Rac/Ri), obtaining a second ratio of a third thermal resistance (Rc), which is between the target area temperature and an external casing temperature, and the second thermal resistance (Ri), which is between the in-machine temperature and the target area temperature through a second calibration procedure, calculating a predicting external casing temperature (Tskin) according to, Tskin=Tb−(Ta−Tb)×(Rc/Ri), to control the activation and speed of a fan according to the in-machine temperature, the predicting external casing temperature, and the predicting external ambient temperature, and/or to optimize sustained computing power for AI laptop.

The disclosure further provides a temperature sensing method used for an AI laptop, the temperature sensing method including: sensing an in-machine temperature (Ta) and a target area temperature (Tb); obtaining a first ratio of a first thermal resistance (Rac), which is between the target area temperature and an external ambient temperature, and a second thermal resistance (Ri), which is between the in-machine temperature and the target area temperature through a first calibration procedure; calculating a predicting external ambient temperature (Tamb) according to: Tamb=Tb−(Ta−Tb)×(Rac/Ri); according to the in-machine temperature, the target area temperature, and the predicting external ambient temperature, to control the activation and speed of a fan, and/or to optimize sustained computing power for AI laptop.

In summary, the temperature sensing unit used for the AI laptop of the disclosure is using the non-contact temperature sensor to simultaneously obtain three types of temperature characteristics, which are the laptop's internal temperature (in-machine temperature (Ta)), the target area temperature (such as the keyboard temperature), and the ambient temperature (external ambient temperature), to optimize the computing power and reduce fan noise. Specifically, the temperature sensing unit and the temperature sensing method used for the AI laptop of the disclosure may not only measure the surface temperature of the target area, but also estimate the external surface temperature and the ambient temperature of the target area for heat management of the laptop to provide optimized sustained computing power.

### BRIEF DESCRIPTION OF THE DRAWINGS

FIG. 1 is time sequence of the traditional method of controlling air volume and heat dissipation using a temperature sensor built into the chip.

FIG. 2 is time sequence of the traditional method of controlling air volume and heat dissipation using a thermistor.

FIG. 3 is time sequence of proposed method of controlling air volume and heat dissipation using a non-contact thermopile sensor.

FIG. 4(a) is the schematic diagram of the application of the disclosure. FIG. 4(b) is the schematic diagram of calculating the predicting ambient temperature through the target area temperature, casing temperature, and in-machine temperature. FIG. 4(c) is the schematic diagram of calculating the predicting ambient temperature through the target area temperature and in-machine temperature.

FIG. 5 is the curve graph of predicting external ambient temperature under varied heat source during experiment.

FIG. 6 is the schematic diagram of the dual thermopile sensing element of the embodiment in the disclosure.

FIG. 7 is the exploded diagram of the dual thermopile sensing element of the embodiment in the disclosure.

FIG. 8 is the flowchart of the temperature sensing method of the disclosure.

FIG. 9 is the flowchart of another temperature sensing method of the disclosure.

### DETAILED DESCRIPTION

As used in the present disclosure, terms such as “first”, “second” are employed to describe various elements, components, regions, layers, and/or parts. These terms should not be construed as limitations on the mentioned elements, components, regions, layers, and/or parts. Instead, they are used merely for distinguishing one element, component, region, layer, or part from another. Unless explicitly indicated in the context, the usage of terms such as “first”, “second” does not imply any specific sequence or order.

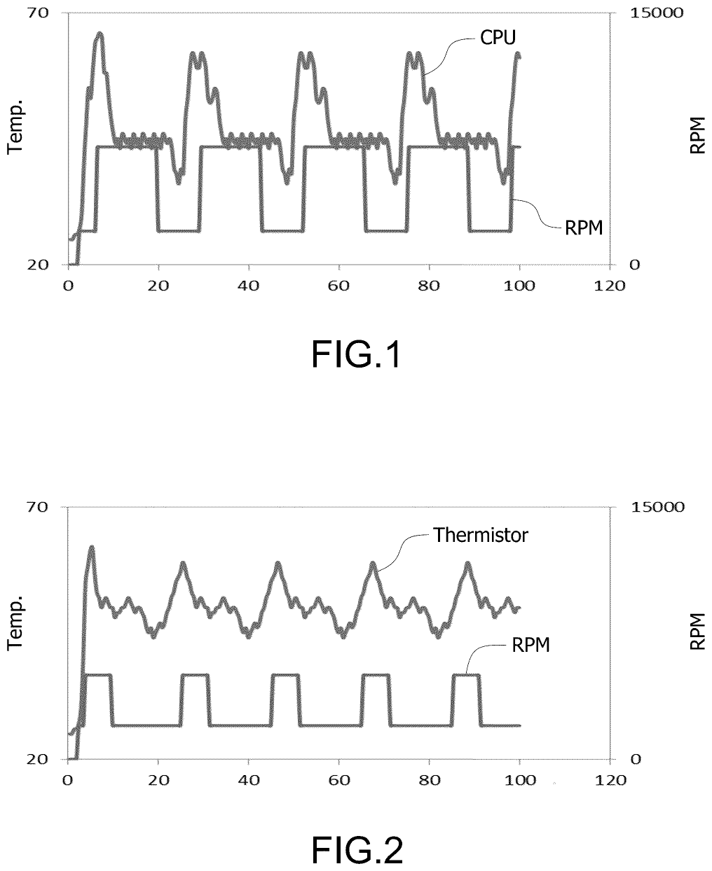

FIG. 1 is time sequence of the traditional method of controlling air volume and heat dissipation using a temperature sensor built into the chip. The upper curve is the target area temperature (CPU temperature) and the lower curve is variation of the fan speed. The rotational speed of the fan is increasing following increasing of the CPU's temperature, and is decreasing following decreasing of the CPU's temperature with some time delay. Thus, the variation frequency of the rotational speed is frequently changed with respect to the CPU's temperature variation. The fan noise in this manner is the most annoying one that has worst user experience.

FIG. 2 is time sequence of the traditional method of controlling air volume and heat dissipation using a thermistor. The thermistor is generally disposed on the main board. The upper curve is the target area temperature (main board temperature) and the lower curve is variation of the fan's air volume. The rotational speed of the fan is increasing following increasing of the temperature sensed by the thermistor, and is decreasing following decreasing of the temperature sensed by the thermistor. Thus, the variation frequency of the rotational speed is frequently changed with respect to the main board's temperature variation. The thermistor is a contact type temperature sensor. Although the variation range of the temperature information from the thermistor is smaller than that of the temperature sensor in the CPU, but the fundamental problem is not solved. Thus, the fan noise in this manner is slightly improved, but the user experience is still not good enough.

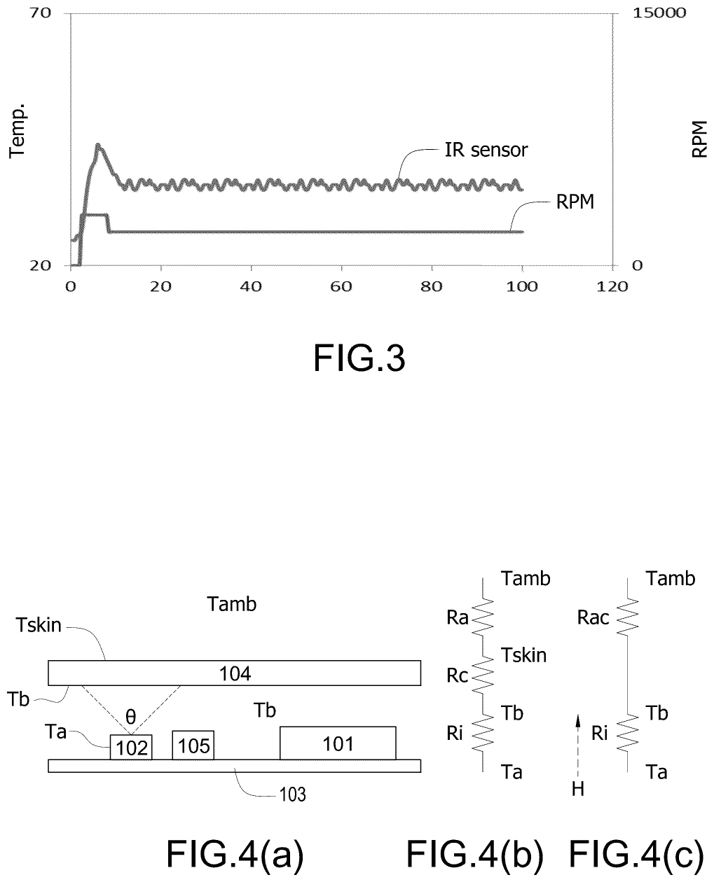

FIG. 3 is time sequence of proposed method of controlling air volume and heat dissipation using a non-contact thermopile sensor. The target temperature measured by the infrared temperature sensor is the element casing temperature of the laptop, that is far from the heat source, and the influence of thermal shock from the CPU may be omitted. The temperature being measured is equivalent to the average temperature of the dramatically changed CPU temperature passing through the low pass filter. Thus, the temperature is more stable to be an ideal temperature for feedback temperature control. The fan noise in this manner is the lowest, and the user experience is the best.

In the usage of AI laptop, the key concern is to provide sustained computing power. Therefore, the signals such as the target area temperature, the in-machine temperature, and the ambient temperature (external ambient temperature) may be used for temperature controlling. Particularly, the ambient temperature may influence the sustained computing power to be provided.

The temperature sensing unit of the disclosure includes the non-contact temperature sensor and the processing element. The non-contact temperature sensor is used to measure the target area temperature (Tb) (such as the temperature of the casing or the monitoring point), and the build-in thermistor of the thermopile sensor or the build-in temperature sensor of the processing element may provide the in-machine temperature signal (Ta). The predicting external ambient temperature (Tamb) may be calculated through the calibrated computing parameter and the measured temperature signals (Ta, Tb).

Examples of non-contact temperature sensor including thermopile sensor, thermal-diode sensor or thermistor sensor sitting on membrane with cavity that can detect infrared thermal radiation of external objects.

FIG. 4(a) is the schematic diagram of the application of the disclosure. The non-contact temperature sensor 102 is disposed adjacent to the laptop CPU chip 101. The non-contact temperature sensor 102 is used for monitoring the target area temperature Tb. In the embodiment, the target area temperature Tb is the temperature of the laptop keyboard 104. The laptop substrate 103 is used for carrying the electronic components. The build-in thermistor of the non-contact temperature sensor 102 or the build-in temperature sensor of the processing element 105 may measure the in-machine temperature Ta. The external casing temperature of the laptop keyboard 104 at the target area is Tskin, and the external ambient temperature is Tamb. FIG. 4(b) and FIG. 4(c) shows the model of the temperature at each point and the thermal resistance under the heat flow H. The thermal resistance (first thermal resistance) Ra is between the external casing temperature Tskin of the target area and the ambient temperature Tamb. The thermal resistance (second thermal resistance) Ri is between the in-machine temperature Ta, which is sensed by the non-contact temperature sensor 102 or processing element 105, and the target area temperature Tb. Similarly, the thermal resistance (third thermal resistance) Rc is between the target area temperature Tb and the surface temperature Tskin at the target area. For facilitating analyzing, Ra and Rc may be simplified as Rac as shown in FIG. 4(c) to acquire the ambient temperature Tamb based on the target area temperature Tb.

Under thermal equilibrium, the ambient temperature Tamb may be obtained by the in-machine temperature Ta, the target area temperature Tb, and the first ratio Rac/Ri as shown in equation (1).

$$H = \frac{{T}_{a} - {T}_{b}}{{R}_{i}} = \frac{{T}_{b} - {T}_{amb}}{{R}_{ac}} \to {T}_{amb} - {T}_{b} - ( {T}_{a} - {T}_{b} ) \frac{{R}_{ac}}{{R}_{i}} \qquad ( 1 )$$

The first ratio Rac/Ri may be obtained through the calibration procedure (first calibration procedure). When in use, the predicting ambient temperature (predicting external ambient temperature) Tamb may be obtained according to equation (1) by the measured in-machine temperature Ta and the measured target area temperature Tb. The predicting ambient temperature Tamb and the target area temperature Tb are used to control the activation of the fan and appropriately adjust the air volume to make the laptop chip work under thermal safe zone to provide optimized sustained computing power.

The laptop's computing power is related to the fan's heat dissipation capability as shown below;

The equation of the fan's heat dissipation amount is, Q=0.05 P/ΔTc.

Q is the air volume needed for cooling (unit: Cubic Meter per Minute, CMM). P is the thermal design power (unit: Watts, W). ΔTc is the temperature difference between the chip's working temperature and the external ambient temperature (unit: ° C.).

Presumably, the highest temperature in summer is 35° C. (designed temperature), CPU's allowable case working temperature is 80° C., and the fan's designed air volume is 0.1667 CMM.
1. The conservative designed value of the thermal design power P=0.1667/0.05*(80-35)=150 W.
2. If the realistic external ambient temperature is measured to be 25° C., the realistic thermal design power P=0.1667/0.05*(80−25)=183 W. Therefore the sustained computing power is increased by 22%.
3. If the ambient temperature in winter is measured to be 18° C., the realistic thermal design power P=0.1667/0.05*(80−18)=207 W. Therefore, the sustained computing power is increased by 38%.
4. If the realistic ambient temperature is measured to be 45° C., the realistic thermal design power P=0.1667/0.05*(80−45)=117 W. Hence, the sustained computing power needs to be restricted for safety operation.

The embodiment describes the influence from the ambient temperature to the sustained computing power provided by the laptop in the application of the AI laptop. Therefore, the fan control is related to the chip's optimized computing power, the in-machine temperature Ta, the target area temperature Tb, and the ambient temperature Tamb. The disclosure provides a solution for continuously optimizing the computing power. The disclosure is also used for more precisely predicting the surface temperature of specific area.

Referring to FIG. 4(a), the embodiment uses the in-machine temperature Ta and the target area temperature Tb to calculate the predicting external ambient temperature Tamb based on the equation (1). The thermal resistance ratio Rac/Ri is used, and that may be obtained through the calibration procedure as described below.
Step 1. Heating the circuit board to a specific temperature;
Step 2. Waiting the system to enter a thermal stable state;
Step 3. Measuring the ambient temperature

$${T}_{a m b}^{*}$$

(it may be obtained by measuring outside air of the laptop though the other temperature sensor);
Step 4. Reading out the values of

$${T}_{a}^{*} and {T}_{b}^{*}$$

from the thermopile sensors installed inside;
Step 5. Calculating

$$\frac{{R}_{ac}}{{R}_{i}} = \frac{{T}_{b}^{*} - {T}_{amb}^{*}}{{T}_{a}^{*} - {T}_{b}^{*}} ;$$

Step 6. Repeating the steps 1-5 multiple times (the temperature of the circuit board may be different) to average the reasonable thermal resistance ratio Rac/Ri for multiple temperature measurement as a fixed parameter.

It should be noted that the star (*) sign in variables indicates the measured value during calibration procedure. The thermal resistance ratio Rac/Ri may be stored in the non-volatile memory of the non-contact temperature sensor. In the practical application, the predicting ambient temperature Tamb is obtained by equation (2) based on the measured in-machine temperature Ta, the measured target area temperature Tb, and the thermal resistance ratio Rac/Ri from the calibration procedure. Then the predicting ambient temperature Tamb, the target area temperature Tb, and the in-machine temperature Ta may be used for controlling the fan speed to optimize sustained computing power.

$${T}_{amb} = {T}_{b} - ( {T}_{a} - {T}_{b} ) \frac{{R}_{ac}}{{R}_{i}}$$

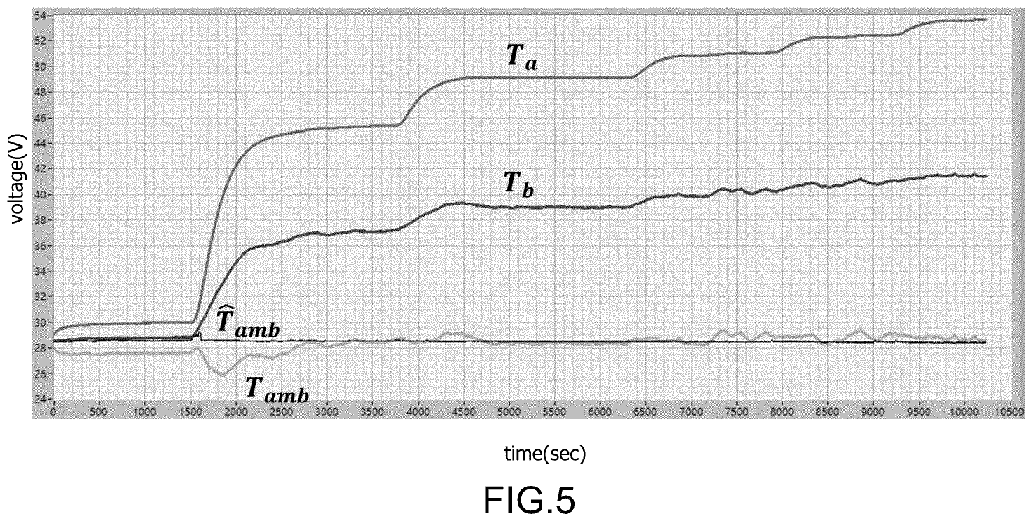

FIG. 5 is the curve graph of predicting external ambient temperature under varied heat source during experiment. From Top to bottom, four curves are the in-machine temperature Ta, the target area temperature Tb, the realistic external ambient temperature \hat{T}amb, and the predicting external ambient temperature Tamb, respectively. As shown in FIG. 5, during the stage that the in-machine temperature Ta is beginning to increased, the predicting external ambient temperature Tamb has an error of about 2° C. comparing to the realistic external ambient temperature \hat{T}amb. Afterward, the predicting external ambient temperature Tamb is substantially the same as the realistic external ambient temperature \hat{T}amb. The estimation error of ambient temperature is larger when the heat source is increasing. Even at the transition stage, the estimation error to the ambient temperature is within 1° C., which proves the effectiveness of the disclosure in predicting the external ambient temperature.

Another embodiment of the disclosure is used for calculating the predicting external casing temperature Tskin at the target area. The thermopile sensor is used to measure the target area temperature Tb, which is the inside surface temperature at the target area. If the surface casing temperature needs to be monitored is not right above the thermopile sensor, for example, at the area laterally distanced×centimeter from the thermopile sensor underneath, the embodiment is still applicable which is shown as equation (3).

$$H = \frac{{T}_{a} - {T}_{b}}{{R}_{i}} = \frac{{T}_{b} - {T}_{skin}}{{R}_{c}} \to {T}_{skin} = {T}_{b} - ( {T}_{a} - {T}_{b} ) \frac{{R}_{c}}{{R}_{i}} \qquad ( 3 )$$

Under thermal equilibrium case, the predicting external casing temperature Tskin may be obtained by the in-machine temperature Ta, the target area temperature Tb, and the second ratio Rc/Ri. The second ratio Rc/Ri may be obtained through the second calibration procedure as shown below;
Step 1. Heating the circuit board to a specific temperature;
Step 2. Waiting the system to enter a stable state;
Step 3. Measuring the external casing temperature

$${T}_{skin}^{*}$$

(it may be obtained by measuring the surface temperature of the laptop's external casing though another temperature sensor);
Step 4. Reading the values of Ta and Tb from the thermopile sensors installed inside;
Step 5. Calculating

$$\frac{{R}_{c}}{{R}_{i}} = \frac{{T}_{b}^{*} - {T}_{skin}^{*}}{{T}_{a}^{*} - {T}_{b}^{*}} ;$$

Step 6. Repeating the steps 1-5 multiple times (the temperature of the circuit board may be different) to obtain averaged Rc/Ri parameter.

The second ratio Rc/Ri may be stored in the non-volatile memory of the non-contact thermopile sensor. In the practical application, the predicting external casing temperature Tskin is obtained by equation (4) based on the measured in-machine temperature Ta, the measured target area temperature Tb, and the second ratio Rc/Ri obtained from the calibration procedure.

$${T}_{skin} = {T}_{b} ( {T}_{a} - {T}_{b} ) \frac{{R}_{c}}{{R}_{t}} \qquad ( 4 )$$

In some embodiments, the non-contact temperature sensor may use a single thermopile sensing element. The single thermopile sensing element may sense the target area temperature Tb, and the build-in thermistor of the single thermopile sensing element may provide the in-machine temperature Ta.

In some other embodiments, the non-contact temperature sensor may use a dual thermopile sensing element (two thermopile sensing elements) for compensating package casing effect and for providing anti thermal shock capability. That is because the internal temperature of the laptop may change abruptly and the normal single thermopile sensor may not be able to provide accurate temperature measurement under the severe heat change condition. One of the dual thermopile sensing elements is used as an active unit for measuring the temperature of the target object, and the other one of the dual thermopile sensing elements is used as a compensation unit (dummy unit) for compensating the influence from the package structure. As a result, the disclosure may precisely measure the temperature under the ambient temperature in severely changing situation. In this condition, the in-machine temperature Ta signal may be obtained by the build-in thermistor of the dual thermopile sensing element or the build-in temperature sensor of the processing element.

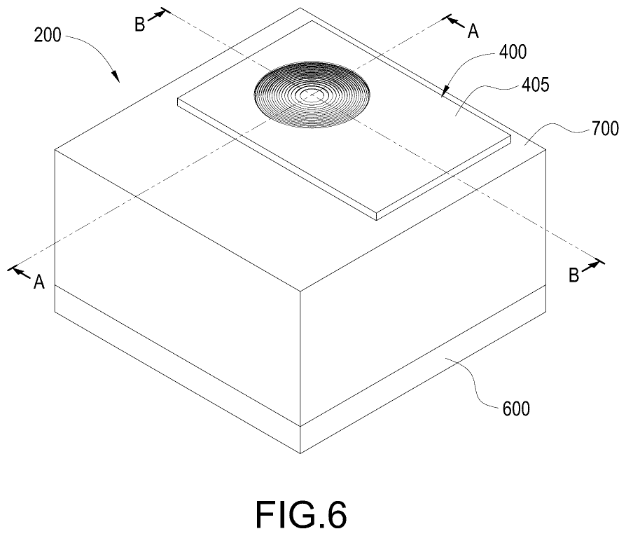

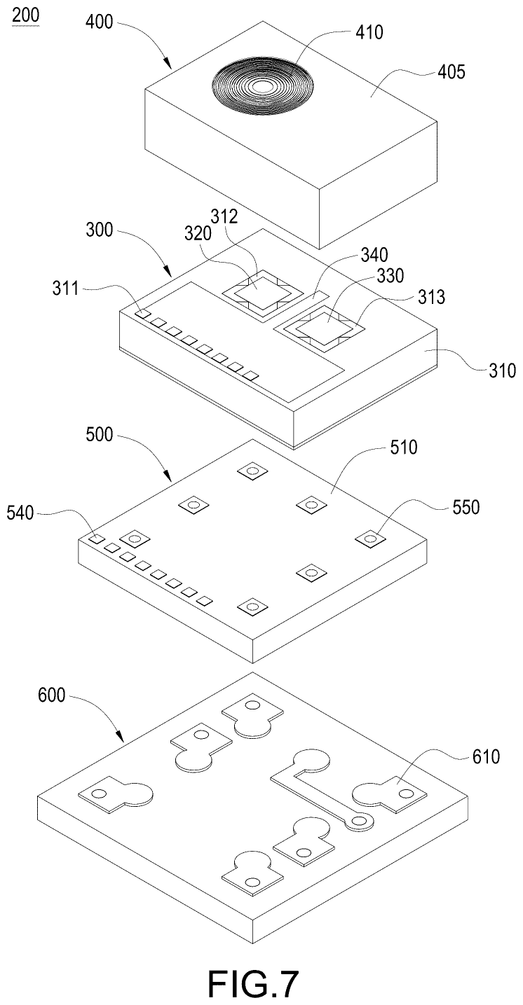

Referring to FIG. 6 and FIG. 7, in some embodiments, the dual thermopile sensing element 200 may, for example, include an infrared sensing chip 300, a silicon cover 400, a microcontroller chip 500, a package substrate 600, and a sealing encapsulation 700.

The infrared sensing chip 300 includes a first substrate 310, a first thermopile sensing element 320, a second thermopile sensing element 330, and a front-end signal processing unit 340. In some embodiments, the first substrate 310 has a wire-bonding pad 311 and two membrane structures (or floating plate structures) 312, 313 formed by a front-side wet etching. The wire-bonding pad 311 and the membrane structures 312, 313 are disposed correspondingly. In some embodiments, the wire-bonding pad 311 is disposed on the edge of the first substrate 310 for wire bonding to the microcontroller chip 500, and the membrane structures 312, 313 are disposed away from the wire-bonding pad 311 and disposed corresponding to the silicon cover 400.

In some embodiments, the first substrate 310 further includes two concave portions 314, 315 corresponding to the membrane structures 312, 313 respectively. In other words, the membrane structure 312 is located above the concave portion 314, and the membrane structure 313 is located above the concave portion 315.

The first thermopile sensing element 320 is disposed on the membrane structure 312 corresponding to the concave portion 314. A hot junction of the first thermopile sensing element 320 is located on the membrane structure 312, and a cold junction of the first thermopile sensing element 320 is located on the periphery of the concave portion 314. The first thermopile sensing element 320 may sense a temperature of the target area to be sensed and generate the target area temperature Tb.

In some embodiments, the second thermopile sensing element 330 is disposed on the membrane structure 313 corresponding to the concave portion 315. The second thermopile sensing element 330 is disposed adjacent to the first thermopile sensing element 320. A hot junction of the second thermopile sensing element 330 is located on the membrane structure 313, and a cold junction of the second thermopile sensing element 330 is located on the periphery of the concave portion 315. The window portion of the second thermopile sensing element 330 is covered by metal, thereby the second thermopile sensing element 330 may merely sense the thermal radiation of the silicon cover 400 to generate a compensation temperature signal.

In some embodiments, the front-end signal processing unit 340 is disposed on the first substrate 310 and electrically connected with the first thermopile sensing element 320 and the second thermopile sensing element 330.

In some embodiments, the infrared Fresnel lens 410 of the silicon cover 400 may be manufactured by a semiconductor process. The first thermopile sensing element 320 is disposed corresponding to the infrared Fresnel lens 410, and the second thermopile sensing element 330 is disposed corresponding to the surface 405 of the silicon cover 400.

It is worth mentioning that the area of the predicting external casing temperature Tskin may be any arbitrary point on the casing, and is not restricted to be right above the internal thermopile sensor for facilitating arranging the layout of the electronic components.

In some embodiments, due to the circuit layout, the target area monitored by the non-contact temperature sensor is different from the ideal monitoring point. In this condition, the in-machine temperature Ta, the predicting external casing temperature Tskin, and the predicting ambient temperature Tamb are used to optimize the sustained computing power and the fan control (ON/OFF and rotational speed).

During calibration process, the external ambient temperature sensor is used to measure the external casing temperature Tskin* and the ambient temperature Tamb* for obtaining two sets of ratio Rac/Ri (used to calculate the predicting ambient temperature Tamb) and Rc/Ri (used to calculating the predicting external casing temperature Tskin). Meanwhile, the optimization control of the laptop's computing power is using the in-machine temperature Ta, the predicting external casing temperature Tskin, and the predicting ambient temperature Tamb.

The first ratio Rac/Ri (calibration parameter) forcalculating the predicting ambient temperature Tamb and the second ratio Rc/Ri (calibration parameter) for calculating the predicting external casing temperature Tskin may be stored in the non-volatile memory of the non-contact thermopile sensor.

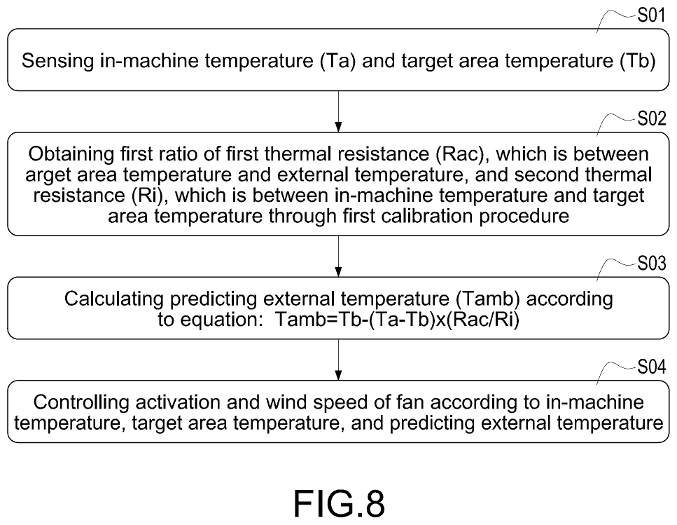

FIG. 8 is the flowchart of the temperature sensing method of the disclosure. The temperature sensing method of the embodiment includes the step S01 to the step S04. The step S01 is sensing the in-machine temperature (Ta) and the target area temperature (Tb). The step S02 is obtaining the first ratio of the first thermal resistance (Rac), which is between the target area temperature and the external ambient temperature, and the second thermal resistance (Ri), which is between the in-machine temperature and the target area temperature through the first calibration procedure. The step S03 is calculating the predicting external ambient temperature (Tamb) according to the equation: Tamb=Tb−(Ta−Tb)×(Rac/Ri). The step S04 is controlling the activation and the speed of the fan according to the in-machine temperature, the target area temperature, and the predicting external ambient temperature. The temperature sensing method of the embodiment may be, for example, achieved by using the aforementioned temperature sensing unit, here is not intended to be limiting. The specific using manner of the temperature sensing method of the embodiment is described in the aforementioned embodiment, here is omitted for brevity.

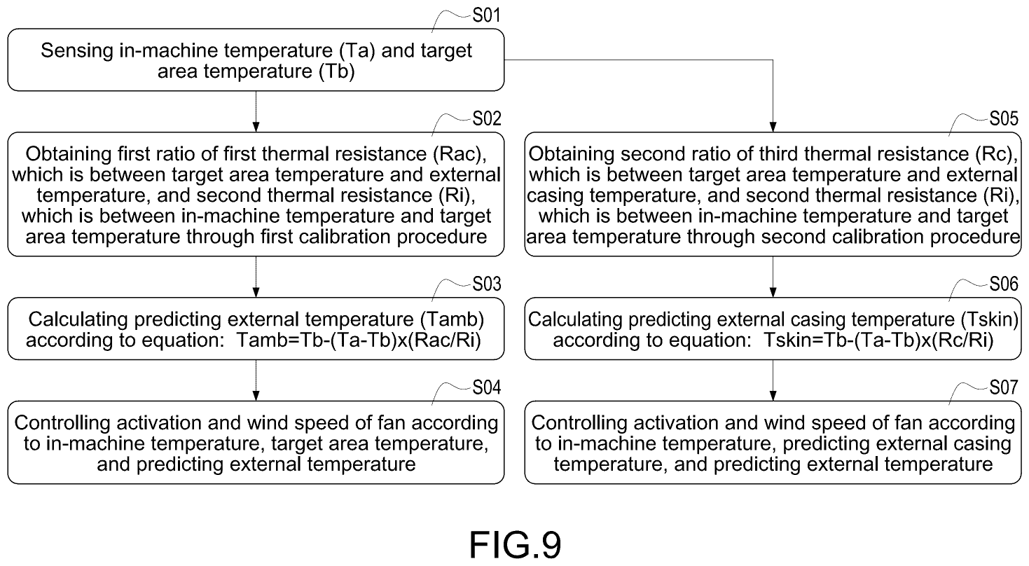

FIG. 9 is the flowchart of the other temperature sensing method of the disclosure. The difference between the temperature sensing method of this embodiment and the temperature sensing method of the above embodiment is that the temperature sensing method of this embodiment further includes the step S05 to the step S07. The step S05 is obtaining the second ratio of the third thermal resistance (Rc), which is between the target area temperature and the external casing temperature, and the second thermal resistance (Ri), which is between the in-machine temperature and the target area temperature through the second calibration procedure. The step S06 is calculating the predicting external casing temperature (Tskin) according to the equation: Tskin=Tb−(Ta−Tb)×(Rc/Ri). The step S07 is controlling the activation and the wind speed of the fan (or fan speed) according to the in-machine temperature, the predicting external casing temperature, and the predicting external ambient temperature. The temperature sensing method of the embodiment may be, for example, achieved by using the aforementioned temperature sensing unit, here is not intended to be limiting. The specific using manner of the temperature sensing method of the embodiment is described in the aforementioned embodiment, here is omitted for brevity. It is worth mentioning that the step S05 to the step S07 may be perform simultaneously the step S02 to the step S04, or the step S05 to the step S07 may be perform before the step S02 to the step S04, or the step S02 to the step S04 may be perform simultaneously the step S05 to the step S07.

In summary, the temperature sensing unit and the temperature sensing method of the disclosure may provide the in-machine temperature (Ta), the target area temperature (Tb), the predicting external casing temperature (Tskin), and the predicting ambient temperature (Tamb). Those temperature signals may be used to control the activation and rotational speed of the fan to decrease the noise of the fan frequently activating and adjust the apparent temperature at keyboard. Further, the disclosure may provide the AI laptop with optimized sustained computing power, which is enhancing the overall efficiency of the laptop's heat management system. In the other embodiment, the non-contact temperature sensor may use the dual thermopile sensing element, one thermopile sensing element is used to measure the target area temperature, and the other thermopile sensing element is used to be a dummy unit for measuring the heat radiation of the cover to provide anti-thermal shock interference capability and more accurate temperature measurement.

While this disclosure has been described by means of specific embodiments, numerous modifications and variations may be made thereto by those skilled in the art without departing from the scope and spirit of this disclosure set forth in the claims.

1. A temperature sensing unit used for an artificial intelligence (AI) laptop, the temperature sensing unit comprising:
a non-contact temperature sensor, configured to sense an in-machine temperature (Ta) and a target area temperature (Tb); and
a processing element, configured to obtain a ratio of a first thermal resistance (Rac), which is between the target area temperature and an external ambient temperature, and a second thermal resistance (Ri), which is between the in-machine temperature and the target area temperature through a calibration procedure, calculate a predicting external ambient temperature (Tamb) according to,
$$Tamb = Tb - ( Ta - Tb ) \times ( Rac / Ri ) , and$$
control an activation of a fan and a fan speed and/or optimize sustained computing power according to the in-machine temperature, the target area temperature, and the predicting external ambient temperature.

2. The temperature sensing unit according to claim 1, wherein the non-contact temperature are thermopile sensor, thermal-diode sensor or thermistor sensor sitting on membrane with cavity that can detect infrared thermal radiation of external objects.

3. The temperature sensing unit according to claim 2, wherein the non-contact thermopile sensor comprises two thermopile sensing elements, one of the thermopile sensing elements is configured to sense the target area temperature, another one of the thermopile sensing elements is a dummy unit and configured to generate a compensation temperature signal.

4. The temperature sensing unit according to claim 2, wherein the in-machine temperature is sensed by a build-in thermistor of the one of the thermopile sensing elements or a build-in temperature sensor of the processing unit.

5. The temperature sensing unit according to claim 2, wherein the non-contact temperature sensor comprises a single thermopile sensing element, the single thermopile sensing element comprises a build-in thermistor configured to sense the in-machine temperature.

6. The temperature sensing unit according to claim 1, wherein the non-contact temperature sensor comprises a non-volatile memory configured to store the ratio of the first thermal resistance and the second thermal resistance.

7. A temperature sensing unit used for an AI laptop, the temperature sensing unit comprising:
a non-contact temperature sensor, configured to sense an in-machine temperature (Ta) and a target area temperature (Tb); and
a processing element, configured to obtain a first ratio of a first thermal resistance (Rac), which is between the target area temperature and an external ambient temperature, and a second thermal resistance (Ri), which is between the in-machine temperature and the target area temperature through a first calibration procedure, calculate a predicting external ambient temperature (Tamb) according to,
$$Tamb = Tb - ( Ta - Tb ) \times ( Rac / Ri ) ,$$
obtain a second ratio of a third thermal resistance (Rc), which is between the target area temperature and an external casing temperature, and the second thermal resistance (Ri), which is between the in-machine temperature and the target area temperature through a second calibration procedure, calculate a predicting external casing temperature (Tskin) according to,
$$Tskin = Tb - ( Ta - Tb ) \times ( Rc / Ri ) , and$$
control an activation of a fan and a fan speed and/or optimize sustained computing power according to the in-machine temperature, the predicting external casing temperature, and the predicting external ambient temperature.

8. The temperature sensing unit according to claim 7, wherein the non-contact temperature are thermopile sensor, thermal-diode sensor or thermistor sensor sitting on membrane with cavity that can detect infrared thermal radiation of external objects.

9. The temperature sensing unit according to claim 8, wherein the non-contact temperature sensor comprises two thermopile sensing elements, one of the thermopile sensing elements is configured to sense the target area temperature, another one of the thermopile sensing elements is a dummy unit and configured to generate a compensation temperature signal.

10. The temperature sensing unit according to claim 9, wherein the one of the thermopile sensing elements is configured to sense the target area temperature, and the processing unit is configured to calculate the predicting external ambient temperature and the predicting external casing temperature according to the first ratio and the second ratio.

11. The temperature sensing unit according to claim 8, wherein the in-machine temperature is sensed by a build-in thermistor of the one of the thermopile sensing elements or a build-in temperature sensor of the processing unit.

12. The temperature sensing unit according to claim 9, wherein the non-contact temperature sensor comprises a single thermopile sensing element, the single thermopile sensing element comprises a build-in thermistor configured to sense the in-machine temperature.

13. The temperature sensing unit according to claim 7, wherein the non-contact temperature sensor comprises a non-volatile memory configured to store the first ratio and the second ratio.

14. A temperature sensing method used for an AI laptop, the temperature sensing method comprising:
sensing an in-machine temperature (Ta) and a target area temperature (Tb);
obtaining a first ratio of a first thermal resistance (Rac), which is between the target area temperature and an external ambient temperature, and a second thermal resistance (Ri), which is between the in-machine temperature and the target area temperature through a first calibration procedure;
calculating a predicting external ambient temperature (Tamb) according to:
$$Tamb = Tb - ( Ta - Tb ) \times ( Rac / Ri ) ; and$$
controlling an activation of a fan and a fan speed and/or optimize sustained computing power according to the in-machine temperature, the target area temperature, and the predicting external ambient temperature.

15. The temperature sensing method according to claim 14, further comprising:
obtaining a second ratio of a third thermal resistance (Rc), which is between the target area temperature and an external casing temperature, and the second thermal resistance (Ri), which is between the in-machine temperature and the target area temperature through a second calibration procedure;
calculating a predicting external casing temperature (Tskin) according to:
$$Tskin = Tb - ( Ta - Tb ) \times ( Rc / Ri ) ; and$$
controlling the activation of the fan and the fan speed according to the in-machine temperature, the predicting external casing temperature, and the predicting external ambient temperature.
